(19) United States
(12) Patent Application Publication
(10) Pub. No.: US 2012/0299131 A1
(43) Pub. Date: Nov. 29, 2012

(54) ARRANGEMENT WITH A MEMS DEVICE AND METHOD OF MANUFACTURING

(75) Inventor: Gudrun Henn, Ebenhausen (DE)

(73) Assignee: EPCOS AG, Munchen (DE)

(21) Appl. No.: 13/472,980

(22) Filed: May 16, 2012

(30) Foreign Application Priority Data
May 23, 2011 (DE) 102011102266.3

(51) Int. Cl. H01L 29/84; H01L 21/56

(52) U.S. Cl. 257/416; 438/127; 257/E29.324; 257/E21.502

(57) ABSTRACT

An arrangement and a production method for the arrangement with at least one MEMS device, which comprises a package that closely encloses the MEMS device and seals it from ambient influences. The package comprises as sealing a PFPE layer of a perfluoropolyether polymerized with the aid of functional groups.

### CROSS-REFERENCE TO RELATED APPLICATION

This application claims the benefit under 35 U.S.C. §119 of Germany Patent Application Serial No. 10 2011 102 266.3, filed in Germany on May 23, 2011, entitled “Arrangement with an MEMS Device and Method of Manufacturing.”

### COPYRIGHT

A portion of the disclosure of this patent document contains material which is subject to copyright protection. The copyright owner has no objection to the facsimile reproduction by anyone of the patent disclosure, as it appears in the Patent and Trademark Office patent files or records, but otherwise reserves all copyright rights whatsoever.

### FIELD OF THE DISCLOSURE

Aspects of the present disclosure relate to an arrangement with an MEMS device and methods of manufacturing the same.

### BACKGROUND

MEMS devices (MEMS=micro-electro-mechanical system) must be protected from mechanical and other environmental influences and for this purpose require a special form of packaging, in which the micromechanical structures are preferably arranged in a cavity, so that an undisturbed function of the structures that can move or vibrate during operation is possible.

As an additional requirement, an MEMS device may require a hermetically sealed package, which is sealed in particular from gases and moisture.

Various technologies for producing cavity packages are known, and have various advantages and disadvantages. In what are known as CSP packages of the latest generation (CSP=chip sized package), the chip with the MEMS device structures is applied to a substrate in a flip-chip arrangement. A frame surrounding the device structures of the MEMS chip serves as a spacing structure. The flip-chip arrangement may subsequently be covered with a polymer, for example by means of lamination or encapsulation.

A better-sealed and easier-to-produce package is obtained if a cover wafer is placed onto a spacing structure enclosing the device structures of the MEMS chip, the device structures being enclosed in a cavity of the package created in this way. Such cover wafers may consist of silicon, glass or piezoelectric materials and preferably coincide with the material of the MEMS chip. The corresponding frame may consist of polymer, metal or metal alloys.

It is also possible to provide a cover wafer with an already pre-structured recess and to place this onto the MEMS chip as a covering in the form of a cap. The bonding may take place with the aid of an adhesive or some other wafer bonding method. However, the latter usually comprise a high-temperature step, which may lead to the MEMS device being damaged.

Other methods for producing a package comprise complex and elaborate steps that are difficult to implement in mass production or unnecessarily increase the effort required for the package, and consequently the costs.

### SUMMARY

An object of the present disclosure is therefore to provide an arrangement with at least one MEMS device that can be produced in an easy and low-cost way, allowing the creation of a hermetic package for the MEMS device. A further object is to provide a method of manufacturing thereof.

These and other objects are achieved according to the invention by an arrangement and method according to the independent claims as originally filed. Advantageous refinements of the invention are provided by further claims.

It is proposed to use for the packaging of the arrangement at least one PFPE (perfluoropolyether) layer as a sealing or covering, which is obtained by polymerization of a perfluoropolyether having functional groups. The MEMS device may in this case be arranged on a substrate and in the arrangement is protected from ambient influences by the package. The PFPE layer serves in the package as a sealing layer.

In U.S. Patent Application Publication No. 2007/0254278 A1, PFPE has, because of its chemical inertness, already been proposed as a material for producing microstructured microfluidic devices, as they are known, which are used in the medical sector.

The PFPE layer comprises a polyether of perfluorinated branched or unbranched alkyl chains. The polyether may comprise branched or unbranched chain links of varying lengths between the oxygen bridges of the polyether. Similarly, the PFPE may have a structure branched by ether bridges.

A PFPE layer that is sealed from ambient influences and used in the invention is preferably completely polymerized and three-dimensionally crosslinked. Such a crosslinked PFPE layer may be obtained from shorter-chain “monomers,” which are provided at the ends with polymerizable or crosslinkable functional groups. Carbon-carbon bonds are preferably formed during the crosslinkage/polymerization, so that the functional groups of the monomers are correspondingly selected and for example comprise an olefinic double bond. The monomers that can be used for producing a PFPE layer themselves represent perfluorinated polyethers, which are for example provided with methacrylate groups as functional crosslinkable groups. Functionalization with crosslinkable styrene groups is also possible.

The perfluorinated alkyl radicals of the polyether give the polymerized material of the PFPE layer strongly hydrophobic properties and therefore make it possible to form a hermetically sealed layer.

Similar to TEFLON®, the PFPE material is also chemically inert and is therefore not attacked even under aggressive conditions. It forms an intimate and close bond with frequently used substrate materials of MEMS devices and can therefore be used well as a sealing layer and as a bonding or adhesive layer.

A further advantage is that the monomers are liquid at room temperature and do not require any solvent for processing. In the course of complete polymerization, the PFPE layer therefore does not lead to gas emissions, not even at elevated temperature. The chemical stability is also combined with a thermal stability, so that no decomposition products or other gas emissions can escape from the PFPE layer, even at elevated temperature, and thereby destroy again the hermeticity of the package.

The PFPE layer may be applied by applying the liquid monomer to the surface to be sealed or covered, and subsequently polymerized by means of irradiation. The irradiation/exposure may take place with a mask or in a structured form, so that the polymerization may result in a structured PFPE layer.

It is also possible, however, to apply the PFPE layer to an intermediate substrate and pre-polymerize it or transform it into a partially crosslinked state, possibly structured. The pre-polymerized or partially crosslinked PFPE layer, which then has for example a gelatinous metastable consistency, may subsequently be transferred to the arrangement with the MEMS device. There, the relatively soft partially crosslinked PFPE layer adapts itself to unevennesses on the underlying surface and can thus even out steps of up to several μm in height or closely envelop such steps. The PFPE layer can therefore also be used for planarizing uneven surfaces and therefore takes the place of additional planarizing layers.

Before the final and complete curing of the PFPE layer by polymerization under irradiation, further PFPE layers may be applied over the first PFPE layer and then chemically crosslinked with this first layer during the curing.

In an embodiment, the PFPE layer is applied to the arrangement over a large surface area. In this case, the PFPE layer covers at least the MEMS device or the device structures thereof. Once the MEMS device has been mounted or arranged on a substrate, the PFPE layer can cover the MEMS device and at least parts of the entire substrate. This has advantages whenever the MEMS device is mounted on the substrate as what is known as a bare die. It is also possible in this way to cover further devices that are arranged on the substrate apart from the MEMS device.

In a further embodiment, the PFPE layer is structured. It can in this form rest on the substrate and the MEMS device or only on the MEMS device or the substrate, covering only part of the arrangement.

In another embodiment, the PFPE layer is arranged in a structured form resting on the MEMS device or the substrate and represents a sealing intermediate layer for a covering. Apart from the sealing function between the substrate or MEMS device and the covering, the intermediate layer may also perform a bonding and adhesive function, in particular if, in the production of the arrangement, application of the PFPE layer to a substrate is followed as a final step by complete crosslinking of the PFPE layer on the substrate. In this case, a solid bond of the PFPE layer to frequently used substrate materials is created, in particular to ceramic, piezoelectric crystals and to metal and glass.

The covering, which lies on the PFPE layer as an intermediate layer, may therefore comprise a plate or a platelet of a ceramic or crystalline material.

For particularly sensitive MEMS devices, the properties of which may be impaired by mechanical stresses, particularly low-distortion packages are obtained if the substrate of the MEMS device comprises the same crystalline or ceramic material as the covering.

The PFPE layer may be formed particularly advantageously as an intermediate layer if it is structured in the form of a frame and at the same time forms a cavity-allowing spacing structure for the covering. The PFPE layer structured in the form of a frame may enclose the device structures of the device on a surface of the MEMS device or may be arranged on the surface of the substrate and enclose at least the MEMS device as a whole. The covering is then arranged in close contact on the PFPE layer structured in the form of a frame and is solidly bonded to it, so that a hermetically sealed cavity is formed between the covering, the PFPE layer and the surface of the MEMS device or of the substrate.

The PFPE layer may comprise at least a first and a second structured partial layer, which rest one on top of the other and are chemically bonded to one another. The first and second PFPE partial layers may then form a three-dimensional structure. In an embodiment, the PFPE layer forms a three-dimensional structure in the form of a cap, which has a recess which is open on one side and, when the cap is placed onto the substrate or the MEMS device, encloses a cavity for the MEMS device structures or for the MEMS device. The cap then sits in a sealing manner on the MEMS device or the substrate and thus protects the MEMS device or the device structures thereof from ambient influences. One partial layer may in this case be applied and structured before the next partial layer is created over it and structured. In this way, a three-dimensional structure is successfully created from partial layers that are differently structured and arranged one on top of the other.

The three-dimensional structure of the PFPE layer may have on one side a multiplicity of recesses, which allow the formation of a corresponding number of cavities, in which an element to be encapsulated or hermetically sealed is then respectively arranged. Each element may be an MEMS device or some other device or part thereof that is to be sealed.

The PFPE layer may also be applied over a large surface area as a sealing layer over an MEMS device mounted on the substrate by the flip-chip technique.

The MEMS device may be selected from micromechanical switches, variable capacitors, sensors, such as for example pressure sensors, or microphones or devices operating with acoustic waves such as SAW (=surface acoustic wave), BAW (=bulk acoustic wave) or GBAW (=guided acoustic wave) devices. Other MEMS devices are also suitable.

Further devices that are sealed together with the MEMS device and a common covering may be provided on the substrate. It is also possible, however, to seal only some of these devices with the PFPE layer or indeed only the MEMS device.

The additional devices may be semiconductor devices, MEMS devices or passive devices or modules that comprise integrated passive and active devices. Integrated passive devices may for example take the form of multilayered structures in which structured metal layers are arranged alternately with dielectric and, in particular, ceramic layers. Plated-through holes between the metallization levels create the electrical connections, so that a multiplicity of passive device structures may be integrated in such a device.

A further covering layer may be built up directly over a covering PFPE layer for sealing or shielding purposes. Such further covering layers that can be applied by thin-film methods and have hermetic properties are preferred. For example, metal layers or dielectric layers deposited from the vapour phase, such as for example oxide layers, nitride layers and the like, are therefore suitable as further covering layers.

It is also possible that the PFPE layer is arranged over a first covering layer formed from a different material. The first covering layer may for example represent the uppermost layer of a thin-film package known per se for MEMS devices, also known as a zero level package. In the case of such a package, a layer structure which comprises a cavity for the sensitive MEMS device structures is created with the aid of thin-film methods. The cavity may be produced for example from a sacrificial layer, which is coated with the mentioned first covering layer. The material of the sacrificial layer can be removed or etched out through preferably lateral etching openings or channels. The etching openings and channels can subsequently be closed. The PFPE layer may serve as a closing layer.

In an embodiment, the MEMS device is an RF device, for example an RF filter.

A possible way of producing the arrangement comprises at least the steps of applying the PFPE layer to the MEMS device or the substrate, the PFPE layer containing along with a perfluoropolyether provided with crosslinkable groups also a photoinitiator. A further production step can comprise the crosslinking of the PFPE layer by means of irradiation, for example by means of UV light. The crosslinking may be performed by polymerization of olefinic crosslinkable groups, for example of styrene or methacrylate groups. The crosslinking make take place directly on the arrangement.

It is also possible, however, to divide the crosslinking into a number of partial steps, all of the partial steps apart from the last partial step leading to an incomplete crosslinkage of the PFPE layer. The dividing into partial steps has the advantage that in this way a number of partial layers, which may be structured differently, can be applied one on top of the other and later bonded to one another. In the last step of complete crosslinkage by means of a sufficient irradiating duration or intensity, the good bonding of the PFPE layer to all of the materials that are in close contact with the PFPE layer in the arrangement is also established.

Aspects of the present disclosure are explained in more detail below on the basis of exemplary embodiments and the associated figures. The figures are only depicted schematically and not true to scale, so that neither absolute nor relative dimensions can be taken from the figures.

### BRIEF DESCRIPTION OF THE DRAWINGS

FIGS. 1A to 1D show various arrangements with an MEMS device on a substrate and a PFPE layer,

FIGS. 2A to 2C show various arrangements of an MEMS device in which the covering sits directly on the MEMS device,

FIGS. 3A to 3E show various embodiments of an arrangement with a number of devices on a substrate and a covering comprising a PFPE layer, and

FIGS. 4A to 4C show an arrangement according to an aspect incorporating an

SAW device.

### DETAILED DESCRIPTION

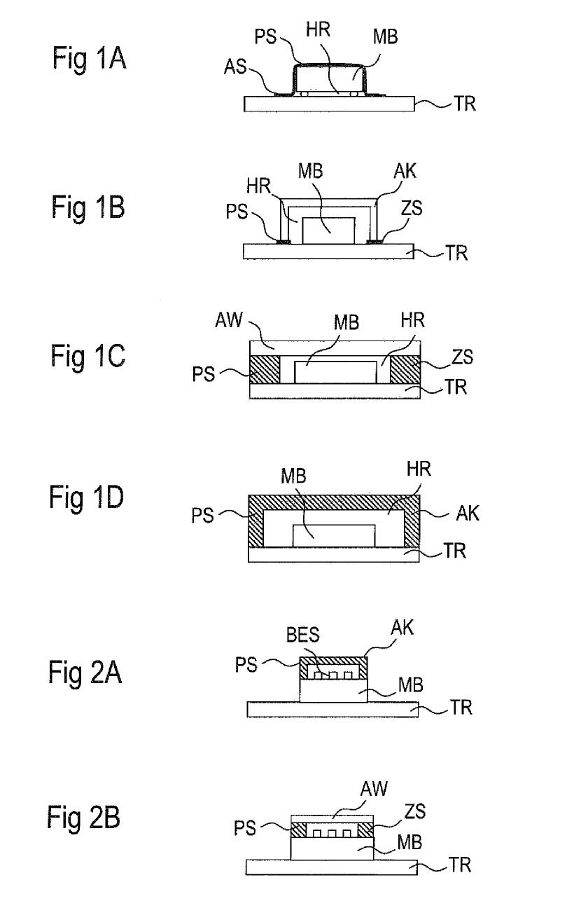

FIG. 1A shows an embodiment of the arrangement according to an aspect of the present disclosure, in which an MEMS device MB is mounted in flip-chip arrangement on a substrate TR. The electrical and mechanical attachment takes place by way of bumps, for example solder or stud bumps. The bumps also act in this case as spacers, so that a gap remains between the substrate TR and the MEMS device MB, and the downwardly facing movable or vibrating device structures of the MEMS device can operate mechanically unimpeded.

For sealing the MEMS device MB from ambient influences, arranged on the upper side of the MEMS device MB is a PFPE layer PS formed as a covering layer AS. This overlaps the edges of the MEMS device MB and finishes with the substrate TR. The PFPE layer PS enters into an intimate, close and solid bond with conventional substrate materials, for example with ceramic, glass or metal, so that, with such a covering layer AS, a hermetically sealed cavity package having a cavity HR is created for the MEMS device. At the same time, the gap is sealed off laterally, so that a sealed cavity HR is formed under the PFPE layer PS between the substrate TR and the MEMS device MB.

FIG. 1B shows a further arrangement, in which the MEMS device MB is again mounted on a substrate. The MEMS device is covered by a covering cap AK and thereby forms a cavity HR, in which the MEMS device MB is arranged. For secure sealing of the cavity HR, a structured intermediate layer ZS, which comprises a PFPE layer PS or consists of a PFPE layer PS, is arranged between the covering cap AK and the substrate TR.

The covering cap AK may be composed of materials that are mechanically adequately strong and can be structured. The covering cap AK is preferably structured from a covering wafer, for example from a glass or ceramic plate of a semiconductor crystal or any other material that can be structured as a solid body. This has the advantage that in this way a multiplicity of covering caps can be structured from the covering wafer, for example by forming corresponding recesses in the underside of the covering wafer, which are then placed on a panel with a multiplicity of MEMS devices and are only separated into individual devices after complete processing. The PFPE layer PS, formed as an intermediate layer ZS, may be structured on the substrate TR or on the underside of the covering cap AK or be applied as an already structured layer to the substrate TR or the covering wafer.

FIG. 1C shows a further embodiment of an arrangement, in which the MEMS device MB is mounted on a substrate TR. A structured PFPE layer PS forms an intermediate layer ZS, which surrounds the MEMS device on the substrate TR and at the same time forms a spacing element, on which a covering formed as a covering wafer AW rests.

This embodiment has the advantage that the covering wafer does not have to be structured and can be placed on as a level and thin wafer. Only the intermediate layer ZS is structured, which once again can take place directly on the substrate TR, directly on the covering wafer AW or separately from the two parts by separate partial crosslinking of a PFPE layer and the subsequent arrangement thereof between the substrate and the covering wafer AW. Here, too, an adequate cavity HR is ensured if the height of the intermediate layer ZS is greater than the height of the MEMS device above the surface of the substrate TR.

FIG. 1D shows an MEMS device MB on a substrate that is covered by a PFPE layer PS formed as a covering cap AK. Such a covering cap AK may be formed by a number of partial layers of a PFPE layer, which are individually structured and in a final crosslinkage are bonded to one another to form a three-dimensional structure, indeed to form the covering cap.

In the embodiments that are shown in FIGS. 1B to 1D, it may remain open how exactly the MEMS device is mounted on the substrate TR. It may be adhesively attached, soldered on or bonded to the substrate in the flip-chip manner of construction. In the first two variants, the electrical connection to the substrate TR may take place by means of bonding wires. Mounting by the SMD technique is also possible.

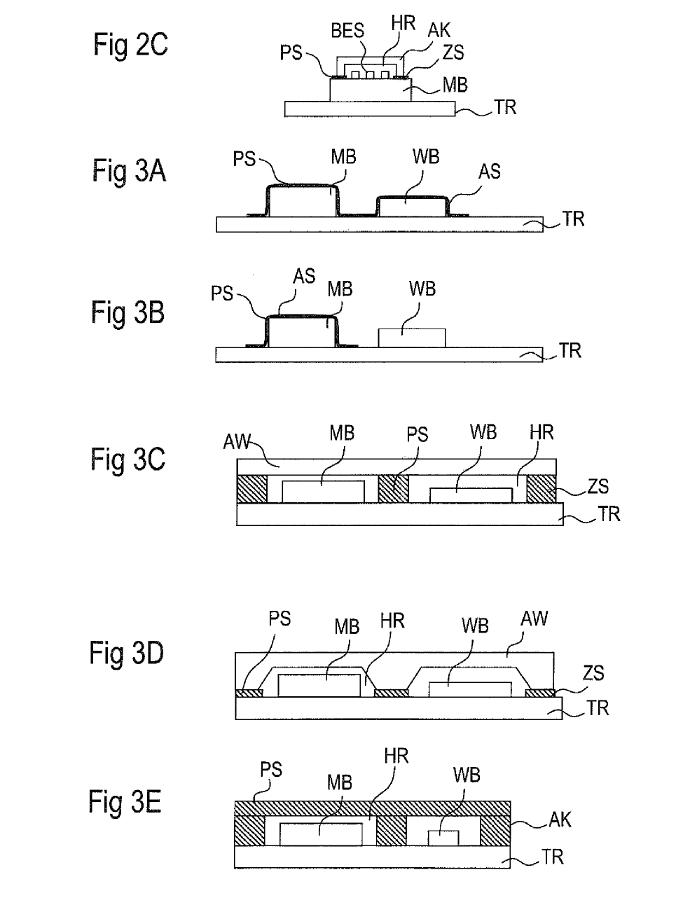

FIGS. 2A to 2C show various embodiments of arrangements according to aspects of the present disclosure, in which the sealing of the device structures takes place directly on the MEMS device MB and can therefore take place already at MEMS wafer level, that is to say before the individual separation of the MEMS devices. In the figures, the MEMS devices MB are arranged on a substrate TR, but they may also represent complete arrangements according to the invention without a substrate.

In FIG. 2A, a covering cap AK, which comprises a PFPE layer PS, is arranged on the MEMS device MB. The covering cap AK encloses underneath it a cavity HR, in which the device structures BES are arranged and thus can operate undisturbed.

The covering cap AK may be formed completely by the PFPE layer PS, or comprise such a layer as a partial layer. In particular, under the PFPE layer PS there may be arranged a further layer of a different material. It is possible for example that the PFPE layer represents the uppermost sealing layer of a thin-film package, which is also known as a zero level package. Various methods are already known for such packages that are produced in an integrated form and leave a cavity HR for the MEMS device structures.

In the case of wafer level packaging, a multiplicity of MEMS devices or MEMS device structures pre-structured on the MEMS wafer may be encapsulated together with a covering cap AK or with a PFPE layer PS provided with recesses. After the individual separation of the MEMS devices, each MEMS device has a covering cap AK of its own.

FIG. 2B shows a covering of the device structures BES by means of a PFPE layer sitting directly on the MEMS device MB and structured to form an intermediate layer ZS, which forms a frame around the device structures BES and on which a covering formed as a covering wafer AW rests. Here, too, the intermediate layer ZS acts as a spacer, so that a cavity HR for the device structures BES is formed between the MEMS device MB and the covering wafer AW.

FIG. 2C shows an arrangement with an MEMS device MB, in which the device structures BES are covered by a structured covering cap AK, which is for example formed from a rigid, preferably ceramic or crystalline material. A PFPE layer PS structured to form an intermediate layer ZS is arranged between the covering cap AK and the surface of the MEMS device MB and provides a sealed closure of the cavity HR under the cap.

FIGS. 3A to 3E show embodiments of the arrangement in which an MEMS device and at least one further device WB are arranged on a substrate TR.

According to FIG. 3A, the two devices are covered by a common covering layer AS, which comprises a PFPE layer as a single layer or as a partial layer of a laminar structure. The covering layer AS finishes in close contact with the substrate TR all around the devices and thus provides a sealed encapsulation of the devices on the substrate.

In the embodiment that is shown in FIG. 3B, only the MEMS device MB is covered by the covering layer AS.

FIG. 3C shows an arrangement in which the MEMS device MB and a further device WB are integrated in a package, which consists of an intermediate layer ZS and a covering, in particular a covering wafer AW. The intermediate layer ZS is structured from a PFPE layer PS, sits on the substrate TR and surrounds the devices in the form of a frame. At the same time, the intermediate layer ZS serves as a spacer and as a support for the preferably rigid covering AW, so that each frame formed in the intermediate layer encloses together with the covering a cavity HR for the respective device.

FIG. 3D shows an arrangement in which a structured PFPE layer PS is arranged as a sealing intermediate layer ZS between a covering, for example a structured covering wafer AW, and the substrate. Respectively enclosed under the covering AW is a cavity HR for the respective device MB, WB, which is substantially formed by a recess in the covering.

FIG. 3E shows an arrangement in which the structured covering AW with the recesses is formed completely by a PFPE layer, which sits directly on the substrate. It is possible here to dispense with the intermediate layer. The covering AW may be built up from a number of structured partial layers.

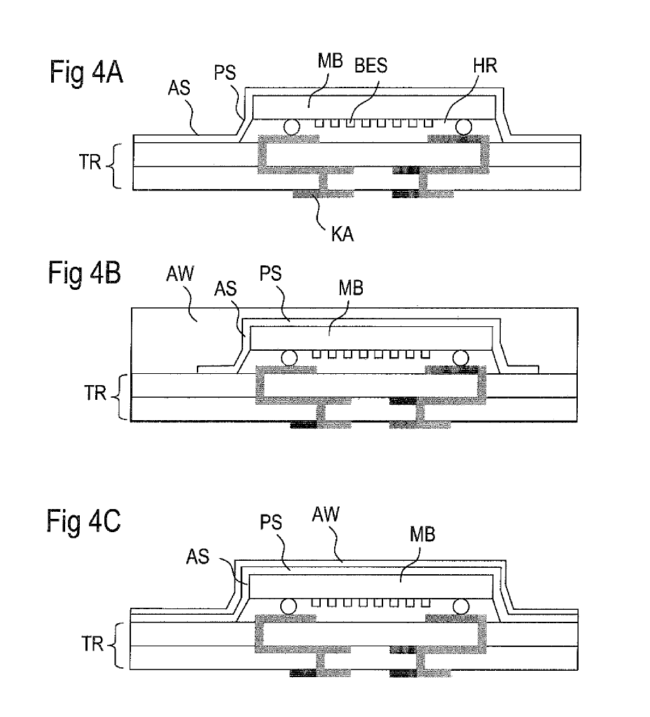

FIG. 4A shows an arrangement in which the structure and possible functions of the substrate TR are presented in more detail. The substrate TR is built up in a multilayered form from dielectric layers, between which structured metallization levels are arranged. Different metallization levels are connected to one another by way of plated-through holes. Provided on the upper side of the substrate TR are connection metallizations for the MEMS device MB and any other further devices there may be. Arranged on the underside of the substrate TR are the external contacts KA, with the aid of which the arrangement can be connected to surrounding circuitry, for example by soldering.

The MEMS device MB is mechanically and electrically connected to the electrical terminal areas of the substrate TR by way of bumps. The device structures BES face downwards and are arranged between the surface of the substrate TR and the MEMS device MB in a clear gap that remains there. Laterally, the gap between the MEMS device and the substrate TR is sealed by means of a covering layer AS, which sits over a large surface area on the upper side of the MEMS device and of the substrate and is formed by a PFPE layer PS. The covering layer AS may be applied with an approximately uniform layer thickness and conformal surface. The covering layer AS may, however, also be applied with a greater layer thickness, for example in a layer thickness reaching up to the upper edge of the MEMS device, so that the MEMS device is virtually buried under the covering layer AS.

The MEMS device is represented here as an SAW device, which comprises a piezoelectric substrate and metallic device structures and terminal pads on the underside of the substrate. The MEMS device may, however, also be a BAW device, in which a layer structure with BAW resonators is formed on the surface of a substrate, for example comprising crystalline silicon. The MEMS device may also be a GBAW device, in which SAW-like device structures are covered by additional layers.

FIG. 4B shows a further refinement in which a relatively thin covering layer AS, formed by a PFPE layer PS, is provided with a further covering layer WA, which has been applied here for example as an encapsulating compound, which completely covers the MEMS device and has a planarized surface. Such a further covering WA may be applied for example as an encapsulating compound and for example by injection moulding.

FIG. 4C shows a further refinement of an arrangement with a further covering WA applied over the covering layer AS, in the form of a thin layer applied with a conformal surface. Such a thin layer is preferably applied by means of thin-film methods from the vapour phase, for example by means of CVD methods, plasma depositing methods or sputtering. It may for example comprise SiO₂ or some other dielectric material.

It is also possible to apply the further covering layer WA as a metal layer and to deposit it for this purpose from a solution. It is also possible to apply a base metallization from the vapour phase and galvanically or electrolessly reinforce it in a solution. A metallic further covering layer WA may be used for electromagnetic shielding. A metal layer can also increase the stability of the package as a whole, and consequently of the arrangement.

The present disclosure is not restricted to the exemplary embodiments that are represented in the figures and described. However, all of these embodiments have in common that the hermetic sealing of the arrangement is performed by the package for the MEMS device by means of a PFPE layer. The PFPE layer may provide the only sealing and covering or, as described, may be formed as an intermediate or bonding layer. An arrangement disclosed herein may also comprise sub-combinations of the exemplary embodiments described or represented.

What is claimed is:

1. Arrangement with at least one MEMS device,
comprising a package enclosing at least the MEMS device and sealing it from ambient influences,
in which the package comprises a PFPE layer of a perfluoropolyether polymerized with the aid of functional groups, the PFPE layer sealing the package from the ambient influences.

2. Arrangement according to claim 1, in which the PFPE layer is structured and covers part of the arrangement.

3. Arrangement according to claim 1,
in which the MEMS device is arranged on a substrate, and
in which the PFPE layer covers the MEMS device over a large surface area, rests at least partially on the substrate, and seals the MEMS device with respect to the substrate.

4. Arrangement according to claim 3, in which the PFPE layer is applied to the MEMS device or to the substrate in a structured form and forms a sealing intermediate layer for a covering arranged thereover.

5. Arrangement according to claim 4, in which the covering comprises a plate or a platelet of a ceramic or crystalline material.

6. Arrangement according to claim 4, in which the MEMS device or the substrate comprises the same crystalline or ceramic material as the covering.

7. Arrangement according to claim 1, in which the PFPE layer is structured in the form of a frame and either (a) rests on a surface of the MEMS device and encloses the device structures thereof or (b) rests on a surface of the substrate and encloses at least the MEMS device, and
in which the covering rests with close contact on the PFPE layer structured in the form of a frame, so that a cavity is formed between the covering, the PFPE layer and the surface of the MEMS device or of the substrate.

8. Arrangement according to claim 1, in which the PFPE layer is structured and comprises at least a first and a second structured partial layer,
in which the second structured partial layer rests on a first partial layer and is chemically bonded to it, and
in which the first and second PFPE partial layers together form a three-dimensional structure.

9. Arrangement according to claim 8, in which the three-dimensional structure takes the form of a cap, defined in which is a recess that is open on one side, and in which the cap sits on the MEMS device or on the substrate in a sealing manner with respect to the surface thereof, so that the device structures or the MEMS device as a whole are arranged in the recess and protected from ambient influences.

10. Arrangement according to claim 8, in which the three-dimensional structure has on one side a multiplicity of recesses, in which a device or the device structures of an MEMS device is/are respectively arranged.

11. Arrangement according to claim 1, in which the PFPE layer is applied over a large surface area as a sealing layer over a MEMS device mounted on the substrate by the flip-chip technique.

12. Arrangement according to claim 1, in which further devices are provided on the substrate and at least one of these devices is sealed with the aid of a large-area or structured PFPE layer.

13. Arrangement according to claim 1,
in which the PFPE layer covers the MEMS device or device structures thereof, and
in which a further covering layer is applied directly over the PFPE layer for sealing or shielding purposes.

14. Arrangement according to claim 13, in which the further covering layer is a metal layer or a dielectric layer deposited from the vapour phase.

15. Arrangement according to claim 1, in which the MEMS device is a micro-structured electromechanical device with a movable part, a sensor or a device operating with acoustic waves.

16. Arrangement according to claim 1, in which the MEMS device is an RF device.

17. Arrangement according to claim 1, in which the functional groups of the PFPE layer are crosslinked methacrylate groups.

18. Method of manufacturing an arrangement with a MEMS device, the method comprising
depositing a covering layer or an interface layer of a PFPE layer onto the arrangement with the MEMS device, the PFPE layer comprising a perfluoropolyether bearing cross-linkable groups, and a photoinitiator, and
cross-linking the PFPE layer by irradiation.

19. The method of claim 18, wherein the cross-linking is done in a structured way by a photomask or a scanning exposure to light.

20. The method of claim 18, wherein
the PFPE layer is first arranged on an intermediate carrier and pre-cross-linked up to a first stage comprising a pre-cross-linked PFPE layer, and
the pre-cross-linked PFPE layer is separated from the intermediate carrier, transferred to the arrangement with the MEMS device and there, finally, completely cross-linked.
